(19) United States
(12) Patent Application Publication
(10) Pub. No.: US 2024/0224598 A1
(43) Pub. Date: Jul. 4, 2024

(54) DISPLAY SUBSTRATE AND METHOD FOR MANUFACTURING THE SAME, AND DISPLAY APPARATUS

(71) Applicants: BEIJING BOE TECHNOLOGY DEVELOPMENT CO., LTD., Beijing (CN); BOE TECHNOLOGY GROUP CO., LTD., Beijing (CN)

(72) Inventor: Wenhai MEI, Beijing (CN)

(73) Assignees: BEIJING BOE TECHNOLOGY DEVELOPMENT CO., LTD., Beijing (CN); BOE TECHNOLOGY GROUP CO., LTD., Beijing (CN)

(21) Appl. No.: 17/916,427

(22) PCT Filed: Nov. 9, 2021
(86) PCT No.: PCT/CN2021/129430

§ 371 Date: Sep. 30, 2022

(30) Foreign Application Priority Data
Mar. 31, 2021 (CN) 202110352002.7

(51) Int. Cl. H10K 59/122; H10K 59/12; H10K 71/13; H10K 102/00

(52) U.S. Cl. CPC H10K 59/122; H10K 59/1201; H10K 71/135; H10K 2102/331

(57) ABSTRACT

A display substrate includes a substrate, first electrodes on the substrate, a first pixel defining layer on the substrate and having first openings, a second pixel defining layer on the first pixel defining layer and having second openings, and light-emitting functional layers on the first electrodes. Each first opening exposes at least a portion of a corresponding first electrode. A sidewall of the first opening is recessed in a direction away from a center of the first opening. On the substrate, an orthographic projection of each second opening at least partially overlaps with an orthographic projection of a corresponding first opening. On the substrate, a border of an orthographic projection of an end of the second opening proximate to the substrate is within a border of an orthographic projection of an end of the second opening away from the substrate. A light-emitting functional layer is in a first opening.

### CROSS-REFERENCE TO RELATED APPLICATIONS

This application is a national phase entry under 35 USC 371 of International Patent Application No. PCT/CN2021/129430, filed on Nov. 9, 2021, which claims priority to Chinese Patent Application No. 202110352002.7, filed on Mar. 31, 2021, which are incorporated herein by reference in their entirety.

### TECHNICAL FIELD

The present disclosure relates to the field of display technologies, and in particular, to a display substrate and a method for manufacturing the same, and a display apparatus.

### BACKGROUND

With the development of quantum dot technologies, people have research on quantum dot light-emitting diode (QLED) display apparatuses deeper and deeper. A quantum efficiency of the QLED display apparatus has been continuously improved and has basically reached a level of industrialization.

At present, it has become one of the development trends in the field to use an ink-jet printing (IJP) technology to fabricate light-emitting functional layers, so as to manufacture a QLED display apparatus having a high resolution.

### SUMMARY

In an aspect, a display substrate is provided. The display substrate includes: a substrate, a plurality of first electrodes, a first pixel defining layer, a second pixel defining layer, and a plurality of light-emitting functional layers.

The plurality of first electrodes are disposed on the substrate. The first pixel defining layer is disposed on the substrate, and the first pixel defining layer has a plurality of first openings, each first opening exposes at least a portion of a corresponding first electrode in the plurality of first electrodes. A sidewall of the first opening is recessed in a direction away from a center of the first opening. The second pixel defining layer is disposed on a side of the first pixel defining layer away from the substrate; the second pixel defining layer has a plurality of second openings, an orthographic projection of each second opening on the substrate at least partially overlaps with an orthographic projection of a corresponding first opening on the substrate. A border of an orthographic projection, on the substrate, of an end of the second opening proximate to the substrate is located within a border of an orthographic projection, on the substrate, of an end of the second opening away from the substrate. The plurality of light-emitting functional layers are located on a side of the plurality of first electrodes away from the substrate, and a single light-emitting functional layer in the plurality of light-emitting functional layers is disposed in a single first opening in the plurality of first openings.

In some embodiments, in a direction that is in a thickness direction of the substrate and from the first pixel defining layer to the second pixel defining layer, areas of sections of the first opening along a direction perpendicular to the thickness direction of the substrate change from small to large and then from large to small.

In some embodiments, the first pixel defining layer is a lyophobic layer; or the first pixel defining layer includes a first substrate material layer, and another lyophobic layer covering at least sidewalls of the first substrate material layer.

In some embodiments, the first pixel defining layer includes inorganic nanoparticles, and ligands bound with the inorganic nanoparticles. A ligand in the ligands includes a fluorine-containing group.

In some embodiments, the first pixel defining layer includes a plurality of silicon oxide nanoparticles, and/or a plurality of silicon nitride nanoparticles.

In some embodiments, the ligand includes at least one of a fluorine atom, trifluoromethyl, hexafluorobenzene group, decafluorobiphenyl group, or perfluoroethylene group.

In some embodiments, in a direction that is in a thickness direction of the substrate and from the first pixel defining layer to the second pixel defining layer, areas of sections of the second opening along a direction perpendicular to the thickness direction of the substrate increase.

In some embodiments, the border of the orthographic projection, on the substrate, of the end of the second opening proximate to the substrate and is located within a border of an orthographic projection, on the substrate, of an end of the first opening away from the substrate.

In some embodiments, the second pixel defining layer is a lyophilic layer; or the second pixel defining layer includes a second substrate material layer, and a lyophilic layer covering at least sidewalls of the second substrate material layer.

In some embodiments, the second pixel defining layer includes a positive photoresist layer.

In some embodiments, an included angle between a sidewall of the second opening and a surface of the second pixel defining layer proximate to the substrate is a range of 30° to 75°, inclusive.

In some embodiments, a ratio of a thickness of the first pixel defining layer to a thickness of the second pixel defining layer is in a range of 1 to 3, inclusive.

In some embodiments, a sum of thicknesses of the first electrode and the light-emitting functional layer is less than a thickness of the first pixel defining layer.

In some embodiments, the display substrate further includes a second electrode layer. The second electrode layer includes second electrodes disposed on a side of the light-emitting functional layers away from the substrate, and a connection pattern covers a surface of the second pixel defining layer away from the substrate and sidewalls of the plurality of second openings.

In another aspect, a display apparatus is provided. The display apparatus includes the display substrate according to any one of the above embodiments.

In yet another aspect, a method for manufacturing a display substrate is provided. The method includes: forming a plurality of first electrodes on a substrate; forming a first pixel defining film and a second pixel defining film on a side of the plurality of first electrodes away from the substrate in sequence; patterning the second pixel defining film to form a second pixel defining layer, the second pixel defining layer having a plurality of second openings, and a border of an orthographic projection, on the substrate, of an end of a second opening in the plurality of second openings proximate to the substrate being located within a border of an orthographic projection, on the substrate, of an end of the second opening away from the substrate; patterning the first pixel defining film by using the second pixel defining layer as a mask to form a first pixel defining layer, the first pixel defining layer having a plurality of first openings, each first opening exposing at least a portion of a corresponding first electrode, an orthographic projection of the first opening on the substrate at least partially overlapping with an orthographic projection of a corresponding second opening in the plurality of second openings on the substrate, and a sidewall of the first opening being recessed in a direction away from a center of the first opening; and forming light-emitting functional layers in the plurality of first openings.

In some embodiments, patterning the first pixel defining film, includes: patterning the first pixel defining film by using a dry etching process.

In some embodiments, forming the light-emitting functional layers in the plurality of first openings, includes: printing an ink for the light-emitting functional layers by using an ink-jet printing in the plurality of first openings; and drying the ink for the light-emitting functional layers to form the light-emitting functional layers.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art can obtain other drawings according to these drawings. In addition, the accompanying drawings to be described below may be regarded as schematic diagrams, and are not limitations on an actual size of a product, an actual process of a method and an actual timing of a signal involved in the embodiments of the present disclosure.

FIG. 1 is a top view of a display substrate, in accordance with some embodiments of the present disclosure;

FIG. 2 is a sectional view of the display substrate as shown in FIG. 1 taken along O-O′;

FIG. 3 is a schematic diagram of an ink-jet printing process, in accordance with some embodiments of the present disclosure;

FIG. 4 is a schematic diagram of another ink-jet printing process, in accordance with some embodiments of the present disclosure;

FIG. 5 is a structural diagram of a display substrate, in accordance with some embodiments of the present disclosure;

FIG. 6 is a structural diagram of another display substrate, in accordance with some embodiments of the present disclosure;

FIG. 7 is a structural diagram of an inorganic nanoparticle bound with a ligand, in accordance with some embodiments of the present disclosure;

FIG. 8 is a structural diagram of a display apparatus, in accordance with some embodiments of the present disclosure;

FIG. 9A is a flowchart of a method for manufacturing a display substrate, in accordance with some embodiments of the present disclosure;

FIG. 9B is a flowchart of another method for manufacturing a display substrate, in accordance with some embodiments of the present disclosure;

FIG. 10 is a diagram illustrating a step for fabricating a first electrode layer, in accordance with some embodiments of the present disclosure;

FIG. 11 is a diagram illustrating a step for fabricating first electrodes, in accordance with some embodiments of the present disclosure;

FIG. 12 is a diagram illustrating steps for fabricating a first pixel defining film and a second pixel defining film, in accordance with some embodiments of the present disclosure;

FIG. 13 is a diagram illustrating steps for fabricating a second pixel defining layer, in accordance with some embodiments of the present disclosure;

FIG. 14 is a diagram illustrating steps for fabricating a first pixel defining layer, in accordance with some embodiments of the present disclosure;

FIG. 15 is a diagram illustrating steps for fabricating light-emitting functional layers, in accordance with some embodiments of the present disclosure;

FIG. 16 is a diagram illustrating steps for fabricating a second electrode layer, in accordance with some embodiments of the present disclosure;

FIG. 17 is a diagram illustrating steps for fabricating an encapsulation layer, in accordance with some embodiments of the present disclosure; and

FIG. 18 is a sectional view of another display substrate as shown in FIG. 1 taken along O-O′.

### DETAILED DESCRIPTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed in an open and inclusive meaning, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representation of the above terms do not necessarily refer to the same embodiment(s) or examples(s). In addition, the specific features, structures, materials or characteristics may be included in any one or more embodiments or examples in any suitable manner.

Hereinafter, the terms “first” and “second” are used for descriptive purposes only, and are not to be construed as indicating or implying the relative importance or implicitly indicating the number of indicated technical features. Thus, a feature defined with “first” or “second” may explicitly or implicitly include one or more of the features. In the description of the embodiments of the present disclosure, the term “a/the plurality of” means two or more unless otherwise specified.

In the description of some embodiments, the terms such as “electrically connected” and derivatives thereof may be used. For example, the term “connected” may be used in the description of some embodiments to indicate that two or more components are in direct physical or electrical contact with each other.

The phrase “A and/or B” includes the following three combinations: only A, only B, and a combination of A and B.

In addition, the use of the phrase “base on” is meant to be open and inclusive, since a process, step, calculation or other action that is “ base on” one or more of the stated conditions or values may, in practice, be based on additional conditions or values beyond those stated.

Exemplary embodiments are described herein with reference to sectional views and/or plan views as idealized exemplary drawings. In the accompanying drawings, thicknesses of layers and sizes of regions are enlarged for clarity. Variations in shapes with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Therefore, the regions shown in the accompanying drawings are schematic in nature, and their shapes are not intended to show actual shapes of regions in an apparatus, and are not intended to limit the scope of the exemplary embodiments.

The ink-jet printing technology is used to print an ink for a light-emitting functional layer in an opening in a pixel defining layer (PDL), and the light-emitting functional layer is formed after the ink is dried. However, in a process of the ink is dried, due to the Marangoni effect, the ink will climb along a sidewall (a barrier wall (a bank)) of the pixel defining layer, so that the formed light-emitting functional layer has a thin middle and thick edges. An uneven thickness of the light-emitting functional layer causes a service life of the light-emitting functional layer reduced, and causes light extraction efficiency of a display apparatus reduced. As a result, the display quality of the display apparatus is affected. Therefore, how to fabricate a light-emitting functional layer with a uniform film thickness has become one of the research directions in the field.

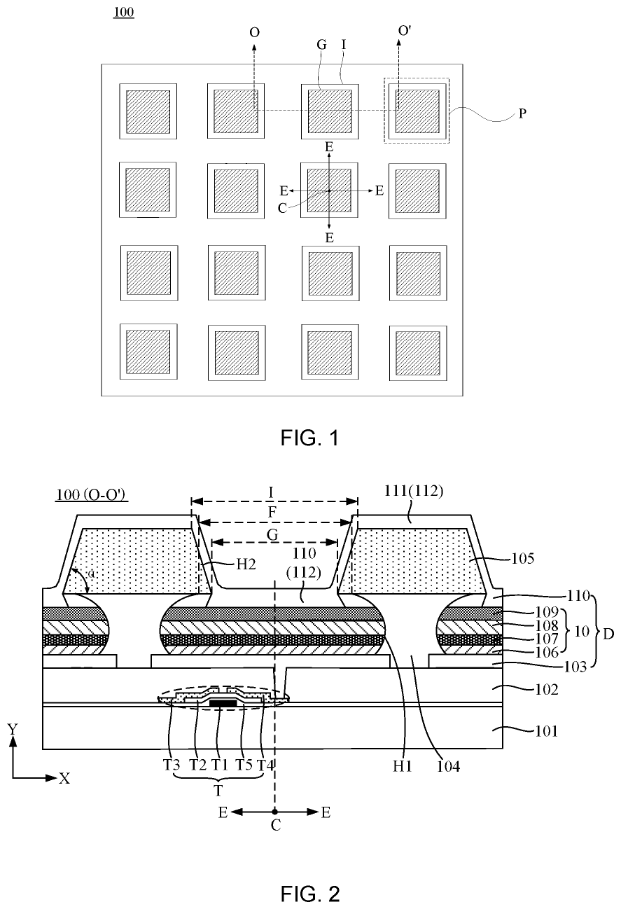

In light this, some embodiments of the present disclosure provide a display substrate. As shown in FIGS. 1 and 2, the display substrate 100 includes a substrate 101 and a plurality of first electrodes 103 disposed on the substrate 101.

It will be noted that, as shown in FIG. 1, the display substrate 100 has a plurality of sub-pixel regions P. The display substrate 100 further includes a plurality of pixel driving circuits disposed on the substrate 101. A pixel driving circuit is disposed in a sub-pixel region P.

As shown in FIG. 2, each pixel driving circuit includes a plurality of thin film transistors T. Each thin film transistor T includes a gate electrode T1, an active layer T2, a source electrode T3 and a drain electrode T4. A gate insulating layer T5 is provided between the gate electrode T1 and the active layer T2 to insulate the gate electrode T1 from the active layer T2.

As shown in FIG. 2, the display substrate 100 further includes a planarization layer 102 disposed on a side of the plurality of pixel driving circuits away from the substrate 101 and covering the plurality of pixel driving circuits. The planarization layer 102 has a plurality of via holes therein. Each first electrode 103 is electrically connected to a source electrode T3 or a drain electrode T4 of a thin film transistor T which serves as a driving transistor in the plurality of thin film transistors T included in a corresponding pixel driving circuit through a via hole in the planarization layer 102 (a case in which the first electrode 103 is electrically connected to the drain electrode T4 is shown in FIG. 2), so that the pixel driving circuit transmits a voltage signal to the first electrode 103.

As shown in FIG. 2, the display substrate 100 further includes a first pixel defining layer 104 disposed on the substrate 101. The first pixel defining layer 104 has a plurality of first openings H1, and the first opening H1 exposes at least a portion of a corresponding first electrode 103. A sidewall of the first opening H1 is recessed in a direction E away from a center C of the first opening H1.

It can be understood that, referring to FIG. 2, a border of an orthographic projection, on the substrate 101, of an end of the first opening H1 proximate to the substrate 101, is located within a border of an orthographic projection of the first electrode 103 on the substrate 101. That is, the end of the first opening H1 proximate to the substrate 101 is shielded by the first electrode 103.

Referring to FIGS. 1 and 2, it can be seen that, directions E start from the center C of the first opening H1, and diverge by 360 degrees in a plane which is perpendicular to a thickness direction of the substrate 101. Portions of the sidewall of the first opening H1 are recessed into the first pixel defining layer 104 along respective directions E that are divergent, so that the first opening H1 with a sectional shape which is as shown in FIG. 2 is formed.

As shown in FIG. 2, the display substrate 100 further includes a second pixel defining layer 105 disposed on a side of the first pixel defining layer 104 away from the substrate 101. The second pixel defining layer 105 has a plurality of second openings H2, an orthographic projection of the second opening H2 on the substrate 101 at least partially overlaps with an orthographic projection of a corresponding first opening H1 on the substrate 101, so that the first openings H1 and the second opening H2 are communicated. As a result, the ink for the light-emitting functional layer may flow into the first opening H1 through the second opening H2.

In addition, a border of an orthographic projection, on the substrate 101, of an end G of the second opening H2 proximate to the substrate 101 is located within a border of an orthographic projection, on the substrate 101, of an end I of the second opening H2 away from the substrate 101.

It can be understood that, referring to FIGS. 1 and 2, an area of the end of the second opening H2 proximate to the substrate 101 is less than an area of the end of the second opening H2 away from the substrate 101, so that the sidewall of the second opening H2 is inclined. For example, a section of the second opening H2 along the thickness direction of the substrate 101 is in a shape of an inverted trapezoid, so that the second opening H2 is in a shape of a “funnel”.

As shown in FIG. 2, the display substrate 100 further includes a plurality of light-emitting functional layers 10 located on a side of the plurality of first electrodes 103 away from the substrate 101. A single light-emitting functional layer 10 is disposed in a single first opening H1.

It will be noted that, an ink-jet printing process may be used to print the ink for the light-emitting functional layer into the first opening H1 in the first pixel defining layer 104 through the second opening H2, and the light-emitting functional layer 10 is formed after the ink is dried.

In addition, as shown in FIG. 2, the display substrate 100 substantially includes light-emitting devices D disposed in the first openings H1. The light-emitting device D includes a first electrode 103 and a light-emitting functional layer 10 that are stacked, and a second electrode 110 disposed on a side of the light-emitting functional layer 10 away from the substrate 101.

By transmitting the voltage signal to the first electrode 103 of the light-emitting device D, and transmitting another voltage signal to the second electrode 110 of the light-emitting device D, a voltage difference is generated between the first electrode 103 and the second electrode 110, so that the light-emitting functional layer 10 between the two is driven to emit light. As a result, an image display of the display apparatus is achieved. For example, the first electrode 103 may be an anode of the light-emitting device D, and the second electrode 110 may be a cathode of the light-emitting device D.

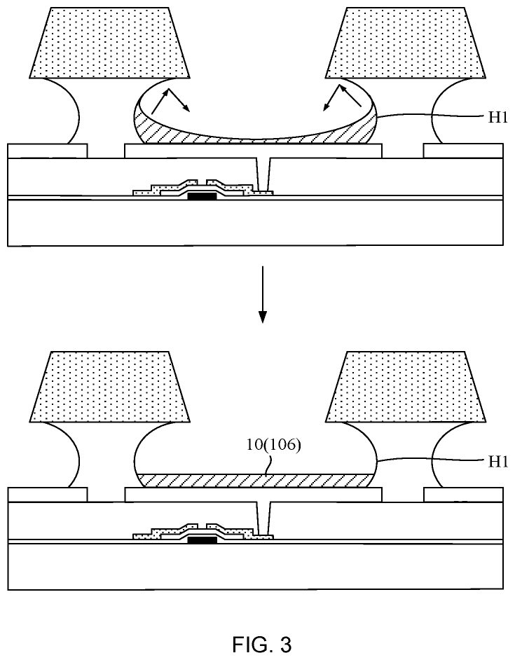

For the display substrate 100 in the embodiments of the present disclosure, by arranging the sidewall of the first opening H1 to be recessed in the direction E away from the center C of the first opening H1, it is possible to attenuate a phenomenon of the ink for the light-emitting functional layer climbing along the sidewall of the first opening H1. In addition, referring to FIG. 3, during a process of the ink climbing along the recessed sidewall of the first opening H1, the ink falls back to a central region of the first opening H1 under an action of gravity. Therefore, after the ink is dried, it helps form the light-emitting functional layer 10 with a relatively uniform film thickness, thereby improving the light-emitting performance and prolonging the service life of the light-emitting functional layer 10.

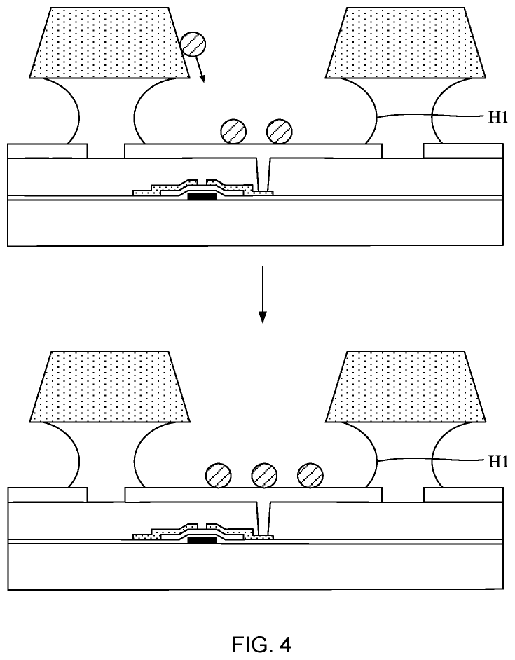

In addition, the border of the orthographic projection, on the substrate 101, of the end G of the second opening H2 proximate to the substrate 101 is located within the border of the orthographic projection, on the substrate 101, of the end I of the second opening H2 away from the substrate 101, so that the sidewall of the second opening H2 is inclined and the second opening H2 is in the shape of the “funnel”. Referring to FIG. 4, in a case where a falling trajectory of the ink deviates or the ink is split into micro ink droplets, the ink may slide down the sidewall of the second opening H2 into the first opening H1 to prevent the ink from flowing to a surface of the second pixel defining layer 105 away from the substrate 101, and to prevent arising a bridge phenomenon of the ink.

In some embodiments, as shown in FIG. 2, the light-emitting functional layer 10 includes at least a light-emitting layer 108.

For example, the light-emitting layer 108 is a quantum dot light-emitting layer. For example, a material of the light-emitting layer 108 may include cadmium selenide (whose chemical formula is CdSe), or zinc sulfide (whose chemical formula is ZnS), or both the cadmium selenide and the zinc sulfide.

In some embodiments, the light-emitting functional layer 10 further includes one or more layers of an electron transport layer (ETL), an electron injection layer (EIL), a hole transport layer (HTL) and a hole injection layer (HIL), so as to improve the light-emitting efficiency of the light-emitting device D.

For example, as shown in FIG. 2, along a direction Y that is in a thickness direction of the substrate 101 and from the first pixel defining layer 104 to the second pixel defining layer 105, the light-emitting functional layer 10 may include: the hole injection layer 106, the hole transport layer 107, the light-emitting layer 108 and the electron transport layer 109 that are stacked in sequence.

For example, a material of the hole injection layer 106 may include polyethylene dioxythiophene (i.e., PEDOT).

For example, a material of the hole transport layer 107 may include poly[(9,9-dioctylfluorenyl-2,7-diyl)-co-(4,4′-(N-p-butylphenyl))diphenylamine] (i.e., TFB).

For example, a material of the electron transport layer 109 may include zinc oxide (whose chemical formula is ZnO).

In some embodiments, as shown in FIG. 2, a sum of thicknesses of the first electrode 103 and the light-emitting functional layer 10 is less than a thickness of the first pixel defining layer 104, so that the light-emitting functional layer 10 may be disposed in the first opening H1 in the first pixel defining layer 104 as a whole.

In some embodiments, as shown in FIG. 2, the display substrate 100 further includes a second electrode layer 112 formed in a whole of layer. The second electrode layer 112 includes second electrodes 110 disposed on a side of the light-emitting functional layers 10 away from the substrate 101, and a connection pattern 111 covering a surface of the second pixel defining layer 105 away from the substrate 101 and sidewalls of the second openings H2.

The second electrodes 110 located in the first openings H1 are electrically connected by the connection pattern 111, which helps reduce an overall impedance of the second electrode layer 112, and may ameliorate the voltage drop (i.e., IR-Drop) generated during the transmission of the voltage signal on the second electrode layer 112.

In some other embodiments, the second electrode layer 112 may be a patterned film layer, and the second electrode layer 112 includes at least the second electrodes 110 disposed on the side of the light-emitting functional layers 10 away from the substrate 101.

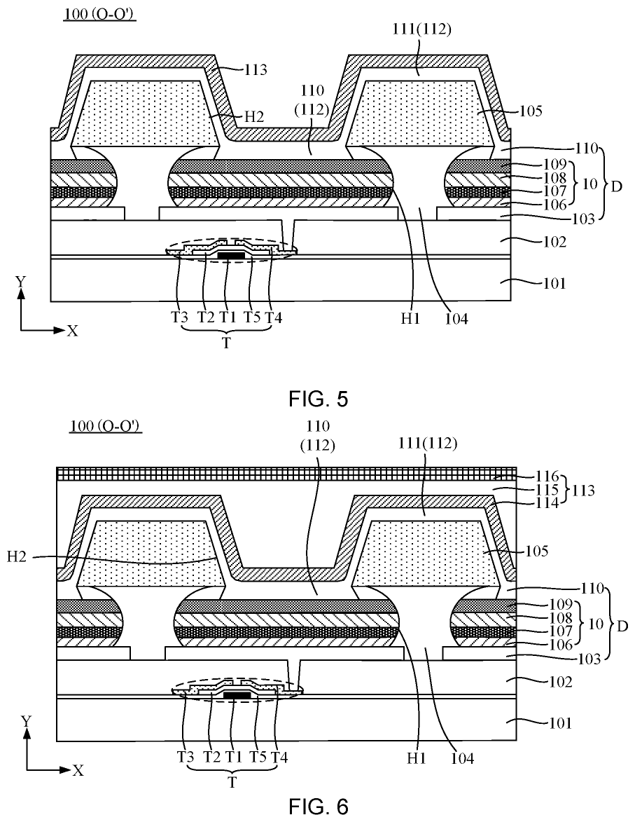

In some embodiments, as shown in FIG. 5, the display substrate 100 further includes an encapsulation layer 113 disposed on a side of the second electrode layer 112 away from the substrate 101. The encapsulation layer 113 includes at least one barrier layer.

For example, as shown in FIG. 5, the encapsulation layer 113 includes a single inorganic barrier layer, which has a function of blocking water vapor and oxygen, and is used to protect film layers under the encapsulation layer 113 in the display substrate 100.

In some embodiments, as shown in FIG. 6, the encapsulation layer 113 may include a first inorganic barrier layer 114, an organic barrier layer 115 and a second inorganic barrier layer 116 that are stacked in sequence in the direction Y that is in the thickness direction of the substrate 101 and from the first pixel defining layer 104 to the second pixel defining layer 105. The organic barrier layer 115 has a certain flexibility, a function of absorbing water vapor, etc., and may achieve a good encapsulation effect together with the first inorganic barrier layer 114 and the second inorganic barrier layer 116.

In some embodiments, as shown in FIG. 2, along the direction Y that is in the thickness direction of the substrate 101 and from the first pixel defining layer 104 to the second pixel defining layer 105, areas of sections of the first opening H1 in a direction X perpendicular to the thickness direction of the substrate 101 change from small to large and then from large to small.

It can be understood that the sidewall of the first opening H1 is recessed in the direction E away from the center C of the first opening H1, and regions, proximate to the two ends, of the sidewall of the first opening H1 are recessed in a relatively small degree, and a region, in a middle region between the two ends of the first opening H1, of the sidewall is recessed in a relatively large degree. By setting the sidewall of the first opening H1 into this shape, the ink falls back to the central region of the first opening H1 under the action of gravity during the process of climbing along the sidewall of the first opening H1.

In some embodiments, the sidewall of the first opening H1 is curved. By setting the sidewall of the first opening H1 to be curved, the sidewall of the first opening H1 is relatively smooth. As a result, it may further attenuate the phenomenon of the ink for the light-emitting functional layer climbing along the sidewall of the first opening H1.

In some embodiments, the first pixel defining layer 104 is a lyophobic layer. That is, a material of the first pixel defining layer 104 includes a lyophobic material. As a result, it may attenuate the phenomenon that the ink for the light-emitting functional layer climbs along the sidewall of the first opening H1 in the first pixel defining layer 104.

It will be noted that the ink for the light-emitting functional layer may be an aqueous solution or an oily solution. The material of the first pixel defining layer 104 includes the lyophobic material, so that the sidewall of the first opening H1 is both hydrophobic and oleophobic. Therefore, regardless of whether the ink for the light-emitting functional layer is water-based or oily, it may attenuate the phenomenon of the ink for the light-emitting functional layer climbing along the sidewall of the first opening H1.

In some other embodiments, as shown in FIG. 18, the first pixel defining layer 104 includes a first substrate material layer 1040, and a lyophobic layer 1041 covering at least sidewalls of the first substrate material layer 1040.

Referring to FIG. 18, a main body of the first pixel defining layer 104 is the first substrate layer 1040, and a material of the main body includes the first substrate material. The lyophobic layer 1041 covers at least the sidewalls of the first substrate material layer 1040. That is, the sidewalls of the first openings H1 are covered with a lyophobic material. As a result, it may also attenuate the phenomenon of the ink for the light-emitting functional layer climbing along the sidewall of the first opening H1.

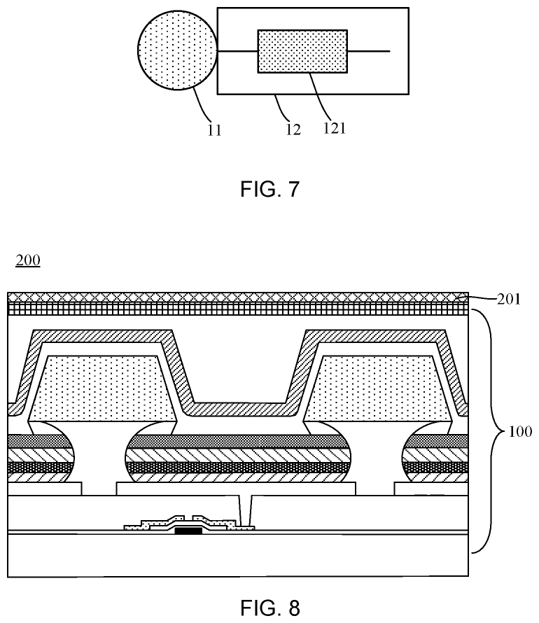

In some embodiments, as shown in FIG. 7, the first pixel defining layer 104 includes inorganic nanoparticles 11 and ligands 12 bound with the inorganic nanoparticles 11. The ligand 12 includes a fluorine-containing group.

It will be noted that, the inorganic nanoparticle 11 is bound with the ligand 12 (the fluorine-containing group), so that the inorganic nanoparticle 11 has hydrophobic and oleophobic properties after bound with the fluorine-containing group.

For example, the inorganic nanoparticle 11 is an insulating material with low conductivity. The first pixel defining layer 104 may include a plurality of silicon oxide nanoparticles. Alternatively, the first pixel defining layer 104 may include a plurality of silicon nitride nanoparticles. Alternatively, the first pixel defining layer 104 may include the plurality of silicon oxide nanoparticles and the plurality of silicon nitride nanoparticles.

For example, the ligand 12 that is bound with the inorganic nanoparticle 11 includes a fluorine-containing group such as at least one of a fluorine atom, trifluoromethyl, hexafluorobenzene group, decafluorobiphenyl group, or perfluoroethylene group. Chemical structural formulas of the trifluoromethyl, hexafluorobenzene, decafluorobiphenyl and perfluoroethylene are as shown in the following (a), (b), (c), and (d), respectively:

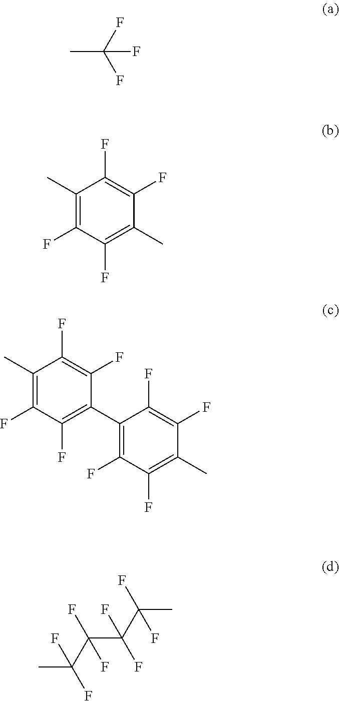

For example, a total chain of the ligand 12 includes 8 to 18 carbon atoms. For example, the total chain of the ligand 12 may include 8 carbon atoms, 10 carbon atoms, 13 carbon atoms, 15 carbon atoms or 18 carbon atoms.

For example, ligand 12 is 1-butyl-4-nonyl tetrafluorobenzene group, and a chemical structure thereof is shown in following (e):

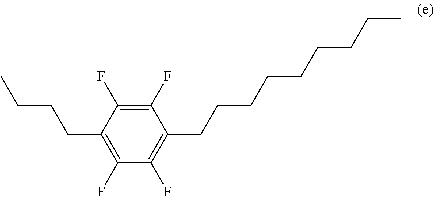 [SMILES: CCCCCCCCCc1c(F)c(F)c(CCCC)c(F)c1F]

In some embodiments, as shown in FIG. 2, in the direction Y that is in the thickness direction of the substrate 101 and from the first pixel defining layer 104 to the second pixel defining layer 105, areas of sections of the second opening H2 along the direction X perpendicular to the thickness direction of the substrate 101 gradually increase.

It can be understood that, referring to FIGS. 1 and 2, the sidewall of the second opening H2 in the second pixel defining layer 105 is inclined, and the area of the end of the second opening H2 proximate to the substrate 101 is less than the area of the end of the second opening H2 away from the substrate 101, so that the section of the second opening H2 along the thickness direction of the substrate 101 is in the shape of the inverted trapezoid. As a result, the ink for the light-emitting functional layer slides down the sidewall of the second opening H2 into the first opening H1 to prevent the ink from flowing onto the surface of the second pixel defining layer 105 away from the substrate 101, and prevent arising the bridge phenomenon of the ink.

In some embodiments, as shown in FIG. 2, an included angle a between the sidewall of the second opening H2 and a surface of the second pixel defining layer 105 proximate to the substrate 101 is in a range of 30° to 75°, inclusive. For example, the included angle α may be 30°, 45°, 50°, 60° or 75°. As a result, it ensures inclination of the sidewall of the second opening H2, so as to ensure that the ink for the light-emitting functional layer may slide down the sidewall of the second opening H2 into the first opening H1.

In some embodiments, the second pixel defining layer 105 is a lyophilic layer. That is, a material of the second pixel defining layer 105 includes a lyophilic material. As a result, it is conducive to flow of the ink for the light-emitting functional layer into the second opening H2 in the second pixel defining layer 105, thereby achieving collection of the ink.

It can be understood that the material of the second pixel defining layer 105 includes the lyophilic material, so that the sidewall of the second opening H2 is both hydrophilic and oleophobic. Therefore, regardless of whether the ink for the light-emitting functional layer is water-based or oily, it is conducive to the guidance of the ink for the light-emitting functional layer by the second opening H2.

In some other embodiments, as shown in FIG. 18, the second pixel defining layer 105 includes a second substrate layer 1050 and a lyophilic layer 1051 covering at least sidewalls of the second substrate layer 1050.

Referring to FIG. 18, a main body of the second pixel defining layer 105 is the second substrate layer 1050, and a material of the main body includes the second substrate material. The lyophilic layer 1051 covers at least the sidewalls of the second substrate layer 1050. That is, the sidewalls of the second openings H2 are covered with the lyophilic material. As a result, it is also conducive to the guidance of the ink for the light-emitting functional layer by the second opening H2.

In some embodiments, the second pixel defining layer 105 includes a positive photoresist layer. That is, a material of the second pixel defining layer 105 includes a positive photoresist (for example, a diazonaphthoquinone photoresist). Therefore, an exposure and developing process may be used to form the plurality of second openings H2 in the second pixel defining layer 105.

In some embodiments, as shown in FIG. 2, the border of the orthographic projection, on the substrate 101, of the end G of the second opening H2 proximate to the substrate 101 is located with a border of an orthographic projection, on the substrate 101, of an end F of the first opening H1 away from the substrate 101.

It can be understood that, the area of the end of the second opening H2 proximate to the substrate 101 is less than an area of the end of the first opening H1 away from the substrate 101, so that the second pixel defining layer 105 may shield an edge region of the end of the first opening H1 away from the substrate 101, which may play a role of blocking the ink for the light-emitting functional layer to prevent the ink from splashing out from the first opening H1. In addition, the climbing path of the ink is extended. Even if the ink climbs along the sidewall of the first opening H1 to the surface of the second pixel defining layer 105 proximate to the substrate 101, the ink will also fall back to the central region of the first opening H1 under the action of gravity, thereby avoiding the ink climbing along the sidewall of the first opening H1 into the second opening H2 in the second pixel defining layer 105.

In some embodiments, a ratio of the thickness of the first pixel defining layer 104 to a thickness of the second pixel defining layer 105 is in a range of 1 to 3, inclusive. For example, the ratio is 1, 1.5, 2, 2.6 or 3. That is, the thickness of the first pixel defining layer 104 may be equal to the thickness of the second pixel defining layer 105, or the thickness of the first pixel defining layer 104 may be greater than the thickness of the second pixel defining layer 105.

Some embodiments of the present disclosure provide a display apparatus. As shown in FIG. 8, the display apparatus 200 includes the display substrate 100 and a polarizer 201 disposed on a light-exit side of the display substrate 100. By arranging the polarizer 201 on the light-exit side of the display substrate 100, it may be possible to reduce reflection of external ambient light on light-reflecting structures in the display substrate 100, thereby avoiding the influence on the image display of the display apparatus 200.

For the display apparatus 200 in the embodiments of the present disclosure, by setting the sidewall of the first opening H1 in the first pixel defining layer 104 to be recessed in the direction E away from the center C of the first opening H1, the light-emitting functional layer 10 with the relatively uniform film thickness may be formed, which improves the light-emitting performance and prolongs the service life of the light-emitting functional layer 10, thereby improving the display effect of the display apparatus 200.

The display apparatus may be an electroluminescent display apparatus, and the electroluminescent display apparatus may be an organic light-emitting diode (OLED) display apparatus or a quantum dot light-emitting diode (QLED) display apparatus.

The display apparatus 200 may be any device that can display images whether in motion (e.g., videos) or stationary (e.g., static images), and whether textual or graphical. More specifically, it is anticipated that the described embodiments may be implemented in or associated with a variety of electronic apparatuses. The variety of electronic apparatuses are (but not limited to), for example, mobile phones, wireless apparatuses, personal data assistants (PDAs), hand-held or portable computers, GPS receivers/navigators, cameras, MPEG-4 Part 14 (MP4) video players, video cameras, game consoles, watches, clocks, calculators, television monitors, flat panel displays, computer monitors, automobile displays (e.g., odometer displays), navigators, cockpit controllers and/or displays, camera view displays (e.g., rear-view camera displays in vehicles), electronic photos, electronic billboards or signs, projectors, architectural structures, packaging and aesthetic structures (e.g., displays of images of a piece of jewelry).

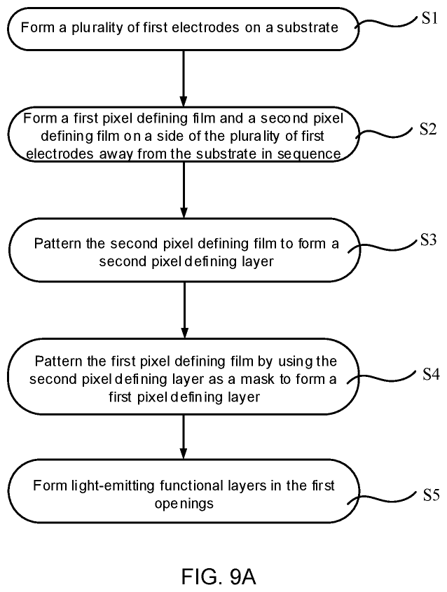

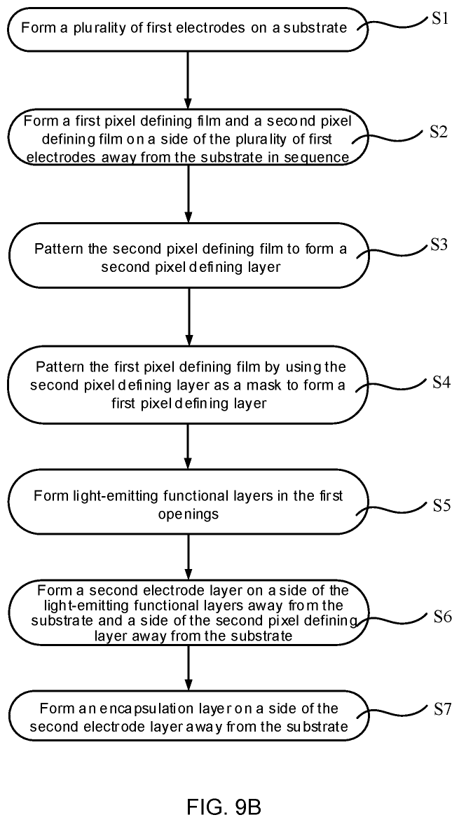

Some embodiments of the present disclosure provide a method for manufacturing a display substrate. As shown in FIG. 9A, the manufacturing method includes S1 to S5 as follows.

In S1, as shown in FIG. 11, a plurality of first electrodes 103 are formed on a substrate 101.

For example, S1 includes S11 and S12 as follows.

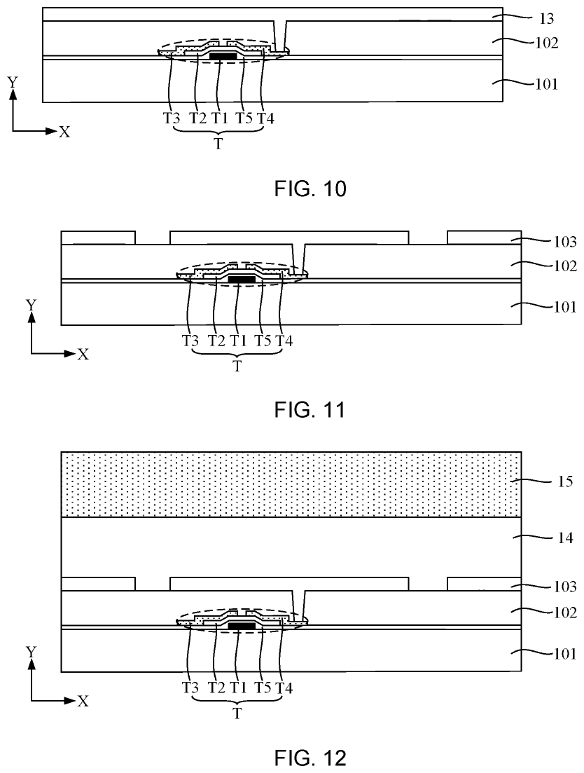

In S11, as shown in FIG. 10, a first electrode layer 13 is formed on the substrate 101 by using a film forming process. The first electrode layer 13 is electrically connected to a drain electrode T4 of a thin film transistor T which serves as a driving transistor in a plurality of thin film transistors T included in a corresponding pixel driving circuit through a via hole in a planarization layer 102.

For example, a material of the first electrode layer 13 includes indium tin oxide (ITO).

In S12, as shown in FIG. 11, the first electrode layer 13 is patterned to form the plurality of first electrodes 103.

For example, a photoresist layer is formed on a side of the first electrode layer 13 away from the substrate 101 by using a photolithography process. Using an etching process, the first electrode layer 13 is etched with using the photoresist layer as a mask, so as to form the plurality of first electrodes 103.

In S2, as shown in FIG. 12, a first pixel defining film 14 and a second pixel defining film 15 are formed on a side of the plurality of first electrodes 103 away from the substrate 101 in sequence.

For example, a side of the plurality of first electrodes 103 away from the substrate 101 is coated with a solution for the first pixel defining film 14 by using a spin coating process, and then the first pixel defining film 14 is obtained after the solution is heated and dried.

For example, the solution for the first pixel defining film 14 is a toluene solution of silicon oxide nanoparticles with a concentration of 500 mg/ml, and a chemical structural formula of a ligand of the first pixel defining film 14 is as shown in following (f):

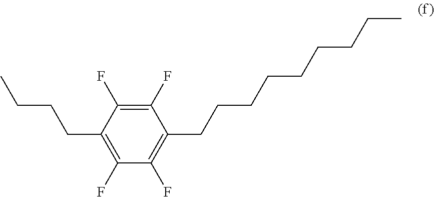 [SMILES: CCCCCCCCCc1c(F)c(F)c(CCCC)c(F)c1F]

The solution for the first pixel defining film 14 is heated for 10 minutes in an environment of 120° C., and then dried to obtain the first pixel defining film 14.

For example, a side of the first pixel defining film 14 away from the substrate 101 is coated with a positive photoresist by using the spin coating process, and the positive photoresist is heated for 90 seconds at 90° C., so as to obtain the second pixel defining film 15.

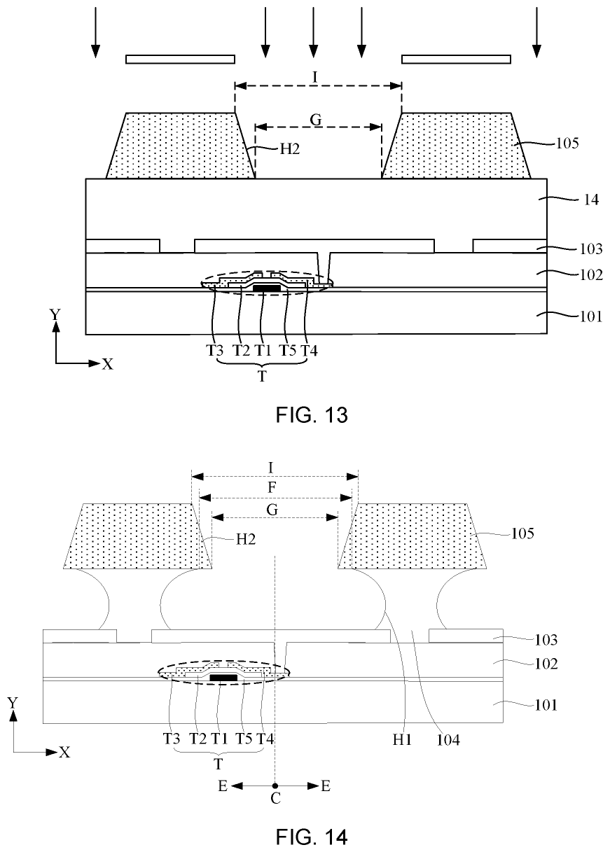

In S3, as shown in FIG. 13, the second pixel defining film 15 is patterned to form a second pixel defining layer 105.

The second pixel defining layer 105 has a plurality of second openings H2, a border of an orthographic projection, on the substrate 101, of an end G of the second openings H2 proximate to the substrate 101 is located within a border of an orthographic projection, on the substrate 101, of an end I of the second openings H2 away from the substrate 101, so that a sidewall of the second opening H2 is inclined, and the second opening H2 is arranged in a shape of a “funnel”. In a case where a falling trajectory of an ink deviates or the ink is split into micro ink droplets, the ink may slide down the sidewall of the second opening H2 into the first opening H1 to prevent the ink from flowing onto a surface of the second pixel defining layer 105 away from the substrate 101, and prevent arising a bridge phenomenon of the ink.

For example, as shown in FIG. 13, the second pixel defining film 15 is a positive photoresist film. When the second pixel defining film 15 is irradiated by ultraviolet light, carboxylate ions will generated in a region of the second pixel defining film 15 irradiated by the ultraviolet light, and the carboxylate ions can be dissolved in alkaline developer. In addition, ultraviolet light is absorbed during passing through the positive photoresist film. Therefore, more carboxylate ions are generated on a surface of the positive photoresist film than that in an inside of the positive photoresist film, so that the surface of the positive photoresist film is dissolved more than the inside of the positive photoresist layer, after development in the alkaline developer. As a result, the funnel-shaped second opening H2 is formed.

For example, the second pixel defining film 15 is exposed by ultraviolet light of 100 millijoules, after exposure is completed, tetramethylammonium hydroxide 2.35% in aqueous solution is used for development, and the second pixel defining layer 105 is formed after the development is completed. The second pixel defining layer 105 may be annealed at 120° C. for 150 seconds, so that solvent is removed to release stress inside the second pixel defining layer 105.

In S4, as shown in FIGS. 13 and 14, the first pixel defining film 14 is patterned by using the second pixel defining layer 105 as a mask to form a first pixel defining layer 104.

The first pixel defining layer 104 has a plurality of first openings H1. The first opening H1 exposes at least a portion of a corresponding first electrode 103, and an orthographic projection of the first opening H1 on the substrate 101 at least partially overlaps with an orthographic projection of a corresponding second opening H2 on the substrate 101. A sidewall of the first opening H1 is recessed in a direction E away from a center C of the first opening H1, so as to attenuate a phenomenon of the ink for a light-emitting functional layer climbing along the sidewall of the first opening H1, which helps form a light-emitting functional layer 10 having a relatively uniform film thickness, so as to improve the light-emitting performance and prolong the service life of the light-emitting functional layer 10.

For example, as shown in FIG. 14, by using a dry etching process, the first pixel defining film 14 is etched with using the second pixel defining layer 105 as a mask, so as to form the plurality of first openings H1.

For example, by using a reactive ion etching (RIE) process, the first pixel defining film 14 is etched anisotropically by etching gas. Referring to FIG. 14, a region of the first pixel defining film 14 not covered by the second pixel defining layer 105 is completely etched, and since the etching gas moves laterally, a region of the first pixel defining film 14 covered by the second pixel defining layer 105 is laterally etched, so that the first opening H1 is formed.

Since a surface of the first pixel defining film 14 away from the substrate 101 is in contact with the second pixel defining layer 105, and a surface of the first pixel defining film 14 proximate to the substrate 101 is in contact with the first electrode 103, so that regions of the sidewall of the first opening H1 closer to the second pixel defining layer 105 and closer to the first electrode 103 have less contact with the etching gas, and a middle region of the sidewall of the first opening H1 in the direction Y has more contact with the etching gas. As a result, the sidewall of the first opening H1 is recessed in the direction E away from the center C of the first opening H1.

A reactive ion etching machine used in the reactive ion etching process has an electrode power of 100 W. The etching gas is trifluoromethane (whose chemical formula is CHF₃), a pressure of the etching gas is 0.5 Pa, and an etching time is 2 min.

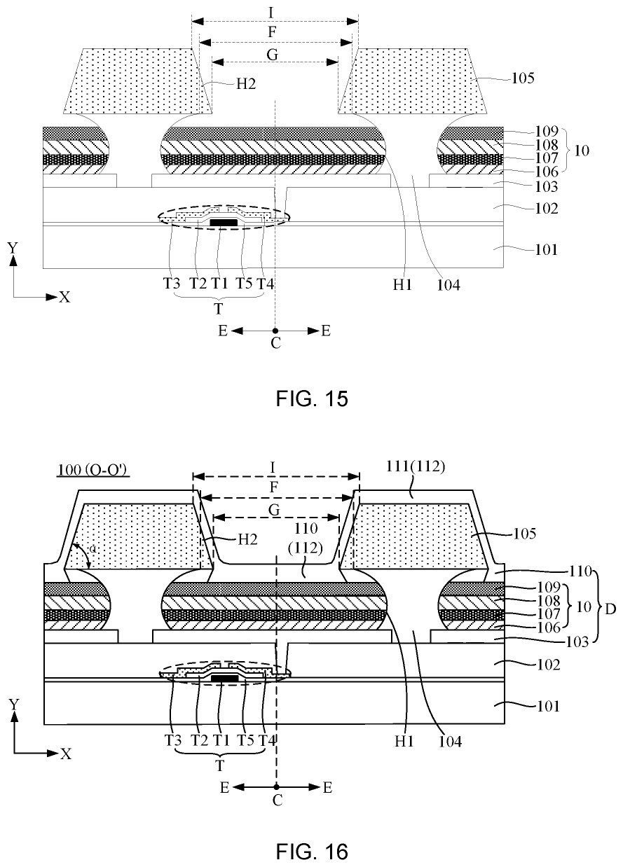

In S5, as shown in FIG. 15, the light-emitting functional layers 10 are formed in the first openings H1.

For example, along the direction Y that is in the thickness direction of the substrate 101 and from the first pixel defining layer 104 to the second pixel defining layer 105, the light-emitting functional layer 10 includes: a hole injection layer 106, the hole transport layer 107, a light-emitting layer 108 and an electron transport layer 109 that are stacked in sequence. In this case, S5 includes S51 to S54 as follows.

In S51, an ink for hole injection layers is printed in the first openings H1 by using an ink-jet printing, and then the ink for the hole injection layers is dried to form the hole injection layers 106.

In S52, an ink for hole transport layers is printed in the first openings H1 by using an ink-jet printing, and then the ink for the hole transport layers is dried to form the hole transport layers 107.

In S53, an ink for light-emitting layers is printed in the first openings H1 by using the ink-jet printing, and then the ink for the light-emitting layers is dried to form the light-emitting layers 108.

In S54, an ink for electron transport layers is printed in the first openings H1 by using the ink-jet printing, and then the ink for the electron transport layers is dried to form the electron transport layers 109.

It will be noted that, in S51 to S54, after the corresponding ink is printed in the first openings H1 by using the ink-jet printing, the ink is vacuumed to remove the solvent therein, so as to shape the film, and then the film is annealed to completely remove the solvent in the ink. Thus, the obtained solute forms a corresponding film.

In some embodiments, as shown in FIG. 9B, after S5, the manufacturing method further includes S6 as follows.

In S6, as shown in FIG. 16, a second electrode layer 112 is formed on a side of the light-emitting functional layers 10 away from the substrate 101 and a side of the second pixel defining layer 105 away from the substrate 101.

For example, as shown in FIG. 16, the second electrode layer 112 is formed in a vacuum environment by using an evaporation process.

In some embodiments, as shown in FIG. 9B, after S6, the manufacturing method further includes S7 as follows.

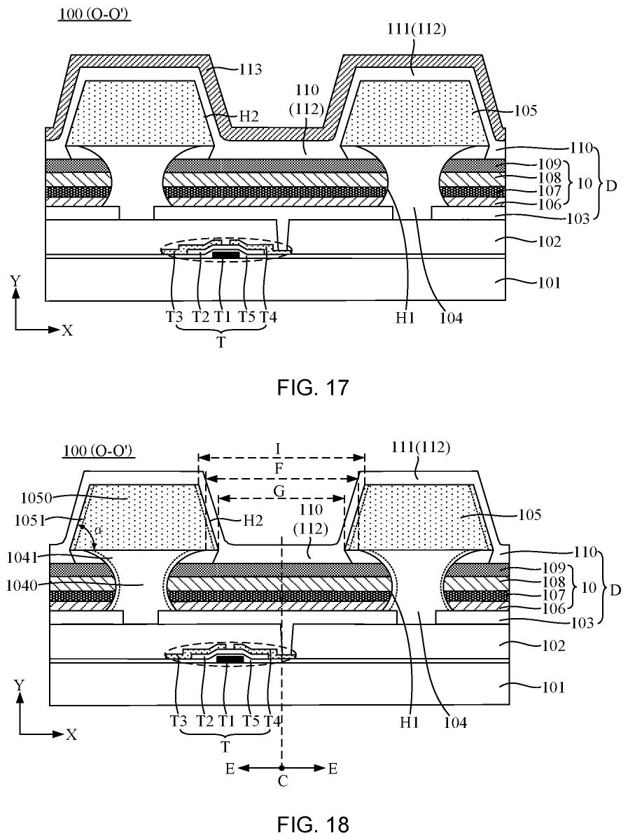

In S7, as shown in FIG. 17, an encapsulation layer 113 is formed on a side of the second electrode layer 112 away from the substrate 101.

The encapsulation layer 113 has a function of blocking water vapor and oxygen, and is used to protect film layers under the encapsulation layer 113 in the display substrate 100.

For example, the encapsulation layer 113 is formed on the side of the second electrode layer 112 away from the substrate 101 by using a chemical vapor deposition (CVD) process.

The foregoing descriptions are merely specific implementations of the present disclosure, but the protection scope of the present disclosure is not limited thereto. Any changes or replacements that a person skilled in the art could readily conceive of within the technical scope of the present disclosure shall be included in the protection scope of the present disclosure. Therefore, the protection scope of the present disclosure shall be subject to the protection scope of the claims.

1. A display substrate, comprising:
a substrate;
a plurality of first electrodes disposed on the substrate;
a first pixel defining layer disposed on the substrate, wherein the first pixel defining layer has a plurality of first openings, each first opening exposes at least a portion of a corresponding first electrode in the plurality of first electrodes; a sidewall of the first opening is recessed in a direction away from a center of the first opening;
a second pixel defining layer disposed on a side of the first pixel defining layer away from the substrate, wherein the second pixel defining layer has a plurality of second openings, an orthographic projection of each second opening on the substrate at least partially overlaps with an orthographic projection of a corresponding first opening on the substrate; a border of an orthographic projection, on the substrate, of an end of the second opening proximate to the substrate is located within a border of an orthographic projection, on the substrate, of an end of the second opening away from the substrate; and
a plurality of light-emitting functional layers located on a side of the plurality of first electrodes away from the substrate, wherein a single light-emitting functional layer in the plurality of light-emitting functional layers is disposed in a single first opening in the plurality of first openings.

2. The display substrate according to claim 1, wherein in a direction that is in a thickness direction of the substrate and from the first pixel defining layer to the second pixel defining layer, areas of sections of the first opening along a direction parallel to a perpendicular to the thickness direction of the substrate change from small to large and then from large to small.

3. The display substrate according to claim 1, wherein the first pixel defining layer is a lyophobic layer; or
the first pixel defining layer includes a first substrate material layer, and another lyophobic layer covering at least sidewalls of the first substrate material layer.

4. The display substrate according to claim 1, wherein the first pixel defining layer includes inorganic nanoparticles, and ligands bound with the inorganic nanoparticles,
wherein a ligand in the ligands includes a fluorine-containing group.

5. The display substrate according to claim 4, wherein the first pixel defining layer includes a plurality of silicon oxide nanoparticles, and/or a plurality of silicon nitride nanoparticles.

6. The display substrate according to claim 4, wherein the ligand includes at least one of a fluorine atom, trifluoromethyl, hexafluorobenzene group, decafluorobiphenyl group, or perfluoroethylene group.

7. The display substrate according to claim 1, wherein in a direction that is in a thickness direction of the substrate and from the first pixel defining layer to the second pixel defining layer, areas of sections of the second opening along a direction perpendicular to the thickness direction of the substrate increase.

8. The display substrate according to claim 1, wherein the border of the orthographic projection, on the substrate, of the end of the second opening proximate to the substrate and is located within a border of an orthographic projection, on the substrate, of an end of the first opening away from the substrate.

9. The display substrate according to claim 1, wherein the second pixel defining layer is a lyophilic layer; or
the second pixel defining layer includes a second substrate material layer, and a lyophilic layer covering at least sidewalls of the second substrate material layer.

10. The display substrate according to claim 1, wherein the second pixel defining layer includes a positive photoresist layer.

11. The display substrate according to claim 1, wherein an included angle between a sidewall of the second opening and a surface of the second pixel defining layer proximate to the substrate is a range of 30° to 75°, inclusive.

12. The display substrate according to claim 1, wherein a ratio of a thickness of the first pixel defining layer to a thickness of the second pixel defining layer is in a range of 1 to 3, inclusive.

13. The display substrate according to claim 1, wherein a sum of thicknesses of the first electrode and the light-emitting functional layer is less than a thickness of the first pixel defining layer.

14. The display substrate according to claim 1, further comprising:
a second electrode layer, the second electrode layer including second electrodes disposed on a side of the light-emitting functional layers away from the substrate, and a connection pattern covering a surface of the second pixel defining layer away from the substrate and sidewalls of the plurality of second openings.

15. A display apparatus, comprising the display substrate according to claim 1.

16. A method for manufacturing a display substrate, comprising:
forming a plurality of first electrodes on a substrate;
forming a first pixel defining film and a second pixel defining film on a side of the plurality of first electrodes away from the substrate in sequence;
patterning the second pixel defining film to form a second pixel defining layer, wherein the second pixel defining layer has a plurality of second openings, and a border of an orthographic projection, on the substrate, of an end of a second opening in the plurality of second openings proximate to the substrate is located within a border of an orthographic projection, on the substrate, of an end of the second opening away from the substrate;
patterning the first pixel defining film by using the second pixel defining layer as a mask to form a first pixel defining layer, wherein the first pixel defining layer has a plurality of first openings, each first opening exposes at least a portion of a corresponding first electrode; an orthographic projection of the first opening on the substrate at least partially overlaps with an orthographic projection of a corresponding second opening in the plurality of second openings on the substrate, and a sidewall of the first opening is recessed in a direction away from a center of the first opening; and
forming light-emitting functional layers in the plurality of first openings.

17. The manufacturing method according to claim 16, wherein patterning the first pixel defining film, includes:
patterning the first pixel defining film by using a dry etching process.

18. The manufacturing method according to claim 16, wherein forming the light-emitting functional layers in the plurality of first openings, includes:
printing an ink for the light-emitting functional layers by using an ink-jet printing in the plurality of first openings; and
drying the ink for the light-emitting functional layers to form the light-emitting functional layers.
